(19) United States
(12) Patent Application Publication
(10) Pub. No.: US 2017/0184698 A1
(43) Pub. Date: Jun. 29, 2017

(54) METHOD AND APPARATUS FOR CALIBRATION OF A DEVICE UNDER TEST

(71) Applicant: Rohde & Schwarz GmbH & Co. KG, Munchen (DE)

(72) Inventor: Johannes Rueth, Herten (DE)

(21) Appl. No.: 14/982,178

(22) Filed: Dec. 29, 2015

(51) Int. Cl. G01R 35/00

(52) U.S. Cl. CPC G01R 35/007; G01R 35/005

(57) ABSTRACT

A method for calibrating a device under test, DUT, comprising the steps of displaying a reference calibration image, oRCI, having at least one marker, M; capturing the displayed reference calibration image, oRCI, to generate a captured reference calibration image, cRCI; and calculating a calibration transformation matrix, CTM, for said device under test, DUT, on the basis of the markers, M, of the original reference calibration image, oRCI, and on the basis of the markers, M′, of the captured reference calibration image, cRCI.

### TECHNICAL FIELD

The invention relates to a method and apparatus for calibrating a device under test DUT, in particular a mobile device such as a laptop or a mobile phone.

Most telecommunication user entities such as mobile phones comprise a display unit to display images to the user. These images can comprise photographs but also images of a video sequence. If an original digital or analog image is displayed by a display unit, processed by a processing unit or transformed there is an impact on the visual quality of the displayed image. The quality of the image or video sequence can be degraded by transforming, processing or displaying the image. The quality degradation of the image can comprise loss of color, pixelation, rotation, scaling or the introduction of image artifacts.

Accordingly, there is a need for calibrating a device under test to optimize a visual quality of an image displayed on a display unit of that device under test.

### SUMMARY OF THE INVENTION

The invention provides according to a first aspect a method for calibrating a device under test comprising the steps of:

displaying a reference calibration image having at least one marker,

capturing the displayed original reference calibration image to generate a captured reference calibration image and

calculating a calibration transformation matrix for the device under test on the basis of the at least one marker of the original reference calibration image and on the basis of the at least one marker of the captured reference calibration image.

In a possible embodiment of the method according to the first aspect of the present invention, the reference calibration image is read from a calibration image database.

In still further possible embodiment of the method according to the first aspect of the present invention, the calibration transformation matrix is calculated by a processing unit of a calibration apparatus depending on markers contained in the original reference calibration image read from a calibration image database and depending on markers contained in the captured reference calibration image.

In a possible embodiment of the method according to the first aspect of the present invention, the reference calibration image is displayed by a display unit of the device under test.

In a further possible embodiment of the method according to the first aspect of the present invention, the reference calibration image displayed on the display unit of the device under test is captured by an image capture component of the device under test or by a camera to generate the captured reference calibration image which is supplied to a calibration apparatus connected to the device under test.

In a further possible embodiment of the method according to the aspect of the present invention, the original reference calibration image read from a calibration image database is transmitted by a base station or by a base station emulation device via a wired or wireless downlink to a receiver of the device under test and displayed on a display unit of the device under test.

In a further possible embodiment of the method according to the first aspect of the present invention, the original reference calibration image read from a calibration image database is displayed on a test screen.

In a further possible embodiment of the method according to the first aspect of the present invention, the reference calibration image displayed on the test screen is captured by a camera connected to the device under test by a camera integrated in the device under test to generate the captured reference calibration image which is supplied to a calibration apparatus.

In a still further possible embodiment of the method according to the first aspect of the present invention, the displayed reference calibration image captured by the camera is transmitted by a transmitter of the device under test via a wired or wireless uplink to a base station or to a base station emulation device connected to the calibration apparatus.

In a still further possible embodiment of the method according to the first aspect of the present invention, the markers of the reference calibration image are positioned at a periphery of the reference calibration image.

In a further possible embodiment of the method according to the first aspect of the present invention, the markers of the reference calibration image comprise unique markers each having a unique form and/or having a unique code pattern.

In still further possible embodiment of the method according to the first aspect of the present invention, the calculated calibration transformation matrix is written in a calibration data memory of the device under test.

In a further possible embodiment of the method according to the first aspect of the present invention, an image to be displayed by a display unit of the device under test is transformed during operation of the device under test using the calibration transformation matrix read from the calibration data memory of the device under test to provide a corrected image output by the display unit of the device under test.

In a still further possible embodiment of the method according to the first aspect of the present invention, the image to be displayed on the display unit of the device under test forms part of a video image sequence.

In a further possible embodiment of the method according to the first aspect of the present invention, a uniform color calibration image is displayed and captured to generate a captured uniform color calibration image comprising superimpositions generated by an application program run on said device under test.

In a still further possible embodiment of the method according to the first aspect of the present invention, the captured uniform color calibration image is transformed using the calculated calibration transformation matrix to calculate a transformed captured uniform color calibration image which is inverted to generate an image mask.

In still further possible embodiment of the method according to the first aspect of the present invention, a test pattern is displayed and captured to generate a captured test pattern which is transformed using the image mask and the calculated calibration transformation matrix which is iteratively modified for geometric fine adjustment and color correction until an error between the captured and transformed test pattern and the original test pattern is minimized.

In a possible embodiment of the method according to the first aspect of the present invention, the fine adjusted modified calibration transformation matrix is written into a calibration data memory of the device under test.

The invention further provides according to a second aspect a calibration system for calibrating a device under test, said calibration system comprising:

means for displaying an original reference calibration image having at least one marker,

means for capturing the displayed reference calibration image to generate a captured reference calibration image and

means for calculating a calibration transformation matrix for the device under test on the basis of at least one marker of the original reference calibration image and on the bass of the at least one marker of the captured reference calibration image.

The invention further provides according to a third aspect a calibration apparatus for calibration of a device under test, said calibration apparatus comprising:

a downlink video performance analyzing unit adapted to analyze a downlink video performance of the device under test, and/or

an uplink video performance analyzing unit adapted to analyze an uplink video performance of the device under test,

wherein the downlink video performance analyzing unit and/or the uplink video performance analyzing unit comprises a processing unit adapted to calculate a calibration transformation matrix of said device under test on the basis of markers of a reference calibration image and on the basis of markers of a captured reference calibration image.

In a possible embodiment of the calibration apparatus according to the third aspect of the present invention, the downlink video performance analyzing unit of said calibration apparatus is adapted to receive a captured reference calibration image on the device under test,

wherein the reference calibration image is captured by an image capture component of the device under test and supplied to said downlink video performance analyzing unit via a data interface or the reference calibration image is captured by a camera connected to the downlink video performance analyzing unit of said calibration apparatus.

In a possible embodiment of the calibration apparatus according to the third aspect of the present invention, the uplink video performance analyzing unit of said calibration apparatus is connected to a test screen adapted to display a reference calibration image,

wherein the reference calibration image displayed on said test screen is captured by a camera connected to the device under test or by a camera integrated in said device under test to generate the captured reference calibration image, which is supplied to the uplink video performance analyzing unit of said calibration apparatus.

In a further possible embodiment of the calibration apparatus according to the third aspect of the present invention, the displayed reference calibration image captured by the camera is transmitted by a transmitter of the device under test via a wireless uplink to a base station or to a base station emulation apparatus connected to the uplink video performance analyzing unit of said calibration apparatus.

The invention further provides according to a fourth aspect a base station emulation apparatus adapted to transmit a reference calibration image via a downlink to a receiver of a device under test, said reference calibration image being displayed by a display unit of the device under test and captured to generate a captured reference calibration image applied to a downlink video performance analyzing unit of a calibration apparatus and

adapted to receive a captured reference calibration image via a uplink from a transmitter of the device under test and to supply the captured reference calibration image to an uplink video performance analyzing unit of the calibration apparatus,

wherein the reference calibration image provided by said uplink video performance analyzing unit of said calibration apparatus is displayed on a test screen and captured by a camera of said device under test.

### BRIEF DESCRIPTION OF FIGURES

In the following, possible embodiments of the different aspects of the present invention are described in more detail with reference to the enclosed figures.

FIG. 1 shows a flowchart of a possible exemplary embodiment of a method for calibrating a device under test according to the first aspect of the present invention;

FIGS. 2A, 2B show schematic diagrams to illustrate the operation of the calibration method shown in FIG. 1 using a simple exemplary reference calibration image;

FIG. 3 shows a block diagram for illustrating schematically the calibration by a device under test with a calibration transformation matrix provided by the method according to the first aspect of the present invention as illustrated in FIG. 1;

FIG. 4 shows a flowchart of a possible exemplary embodiment of a method for calibrating a device under test;

FIG. 5 shows a further flowchart for illustrating a further exemplary embodiment of a method for calibrating a device under test according to the first aspect of the present invention;

FIG. 6 shows a flowchart for illustrating the generation of a mask used for optimizing a calibration transformation matrix which can be used by the method for calibrating a device under test according to the first aspect of the present invention;

FIG. 7 shows schematic diagrams for illustrating the generation of a mask as performed by the process illustrated in FIG. 6;

FIG. 8 shows a flowchart for illustrating the iterative fine adjustment of a calibration transformation matrix which can be used by a method for calibrating a device under test according to the first aspect of the present invention as illustrated in the embodiment shown in FIG. 5;

FIG. 9 shows schematic diagrams for illustrating the optimization process shown in the flowchart of FIG. 8;

FIG. 10 shows a block diagram for illustrating a possible exemplary calibration apparatus according to a further aspect of the present invention used for calibration of a downlink video performance of a device under test;

FIG. 11 shows a block diagram of a possible exemplary embodiment of a calibration apparatus according to an aspect of the present invention used for calibrating an uplink video performance of the device under test;

FIG. 12 shows a block diagram for illustrating the calibration of a device under test by a calibration apparatus as shown in FIGS. 10, 11.

### DETAILED DESCRIPTION OF EMBODIMENTS

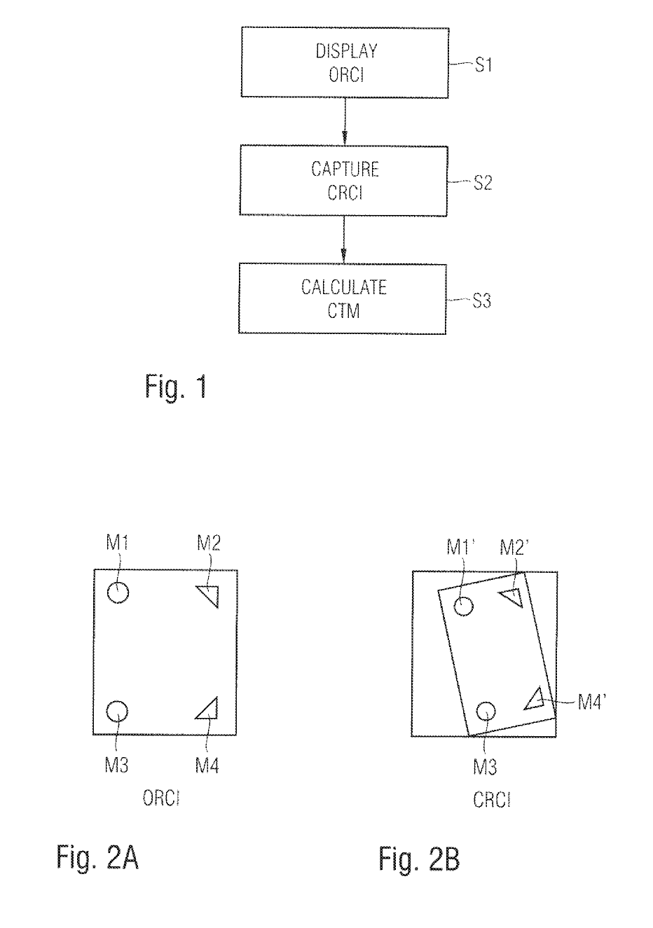

As can be seen in FIG. 1, the method for calibrating a device under test DUT according to the first aspect of the present invention can comprise several steps. In a first step S1, a reference calibration image oRCI having at least one marker M can be displayed. In a possible embodiment, the original reference calibration image oRCI can be read from a calibration image database. FIG. 2A shows an example of a possible original reference calibration image oRCI which can be read from a calibration image database. The reference calibration image comprises in a preferred embodiment markers M which are positioned at a periphery of the reference calibration image. In the exemplary reference calibration image oRCI shown in FIG. 2A, the reference calibration image comprises four markers M1, M2, M3, M4. These markers are positioned at a periphery of the reference calibration image, in particular in the corners of the reference calibration image oRCI. The number of markers M contained in the reference calibration image can vary. The reference calibration image oRCI comprises at least one marker M. The markers M of the reference calibration image comprise in a preferred embodiment a unique form as illustrated in FIG. 2A. The markers M can comprise a specific geometric form such as a triangle or a square such as illustrated in FIG. 2A. In a possible embodiment, the markers M can comprise a unique code pattern. In a possible embodiment, each marker M can comprise at least one QR code pattern. In a preferred embodiment, more than two markers M are used. In a preferred implementation, at least two markers M are contained in the reference calibration image oRCI. The unique identifiable markers M contained in the reference calibration image are displayed on a display unit of a device under test DUT. The device under test can be a mobile communication device such as a smartphone.

In a further step S2 of the method for calibration of the device under test as shown in FIG. 1, a displayed reference calibration image oRCI is captured to generate a captured reference calibration image oRCI as illustrated in FIG. 2B.

In a possible embodiment, the reference calibration image displayed on the display unit of the device under test DUT e.g. on the display unit of a smartphone, is captured by an image software component run on the device under test. The captured reference calibration image cRCI can be supplied by the software component of the device under test DUT via a data interface to a calibration apparatus connected to the device under test. In an alternative embodiment, the reference calibration image is captured by a camera and supplied by the camera to the calibration apparatus. As can be seen in FIG. 2B, the captured reference calibration image cRCI comprises markers M1′, M2′, M3′, M4′ corresponding to the markers M1, M2, M3, M4 in the original calibration image oRCI as shown in FIG. 2A.

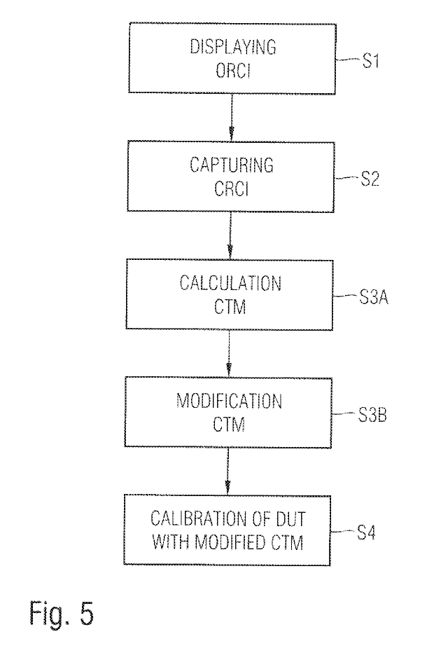

In a further step S3 of the calibration method shown in FIG. 1, a calibration transformation matrix CTM of the device under test is calculated automatically on the basis of the markers M of the original reference calibration image oRCI such as shown in FIG. 2A, and on the basis of the markers of the captured reference calibration image cRCI as shown in FIG. 2B. The processing unit of the calibration apparatus can calculate in a possible embodiment a two-dimensional transformation matrix CTM from the markers M of the original reference calibration image oRCI and from the markers M′ of the captured reference calibration image cRCI. In a possible implementation, the reference calibration image comprises at least one unique QR code pattern. The calculated calibration transformation matrix CTM can then be either directly written into a calibration memory of the device under test DCI or further modified as also illustrated in context with the embodiment shown in FIG. 5.

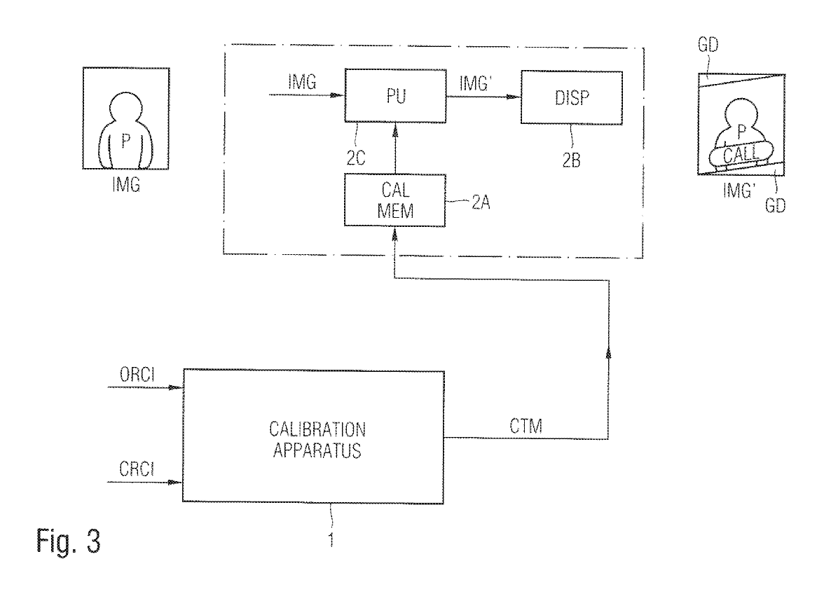

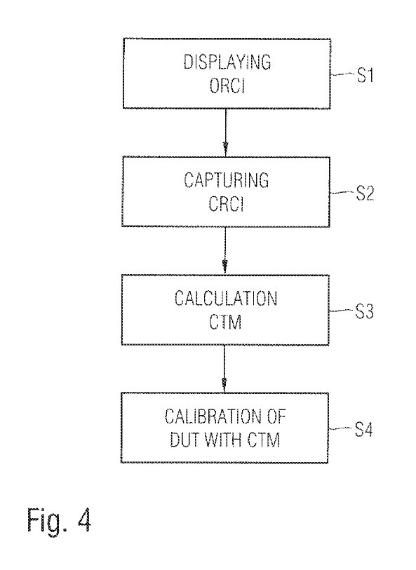

FIG. 3 shows a calibration setup comprising a calibration apparatus 1 according to a further aspect of the present invention adapted to calibrate a device under test 2 which can be formed by a mobile device, in particular a smartphone. The calibration apparatus 1 according to the illustrated embodiment of FIG. 1 comprises a first data interface to receive the original reference calibration image oRCI and a second data interface for receiving the captured reference calibration image cRCI. In a possible embodiment, the original reference calibration image oRCI can be read from a calibration image database and stored in a memory of the calibration apparatus 1 for further processing. The captured reference calibration image cRCI can be supplied from a camera or from a software component capturing the displayed reference calibration image. The calibration apparatus 1 comprises a processing unit adapted to calculate a calibration transformation matrix CTM on the basis of the markers M contained in the original reference calibration image oRCI and on the basis of the markers M′ of the captured reference calibration image cRCI. The calculated calibration transformation matrix CTM can be stored in a memory of the calibration apparatus to be loaded into a calibration memory 2A of the device under test 2 as illustrated in FIG. 3. The device under test 2 as shown in FIG. 3 can for instance comprise a smartphone having a display 2B as shown in FIG. 3. An image IMG is transformed by a processing unit 2C of the device under test to provide a corrected image IMG′ displayed on the display unit 2B of the device under test 2 during its operation. The image IMG can be generated by an application executed on a processing unit 2C of the device under test 2, for instance an application run during a video telephone call. In the example shown in FIG. 3, a person P calling the user of the device under test 2 is displayed during the telephone call on the display unit 2B of the device under test 2. To increase the quality of the displayed image the processing unit 2C is adapted to transform the image IMG provided by the application program using the calculated calibration transformation matrix CTM stored in the calibration memory 2A of the device under test 2 to generate a corrected image IMG′ which is displayed on the display unit 2B of the device under test 2 as shown in FIG. 3. Depending on the application run on the device under test 2, superimpositions can be automatically generated such as a call button displayed on the display unit 2B as shown in FIG. 3. These superimpositions or obstructions can be automatically generated by the respective application program run on the device under test 2. The superimpositions can for instance comprise actuator fields displayed on a touchscreen 2B of the device under test 2 to receive input commands by the respective user U or information data fields displayed to the user on the display unit 2 during execution of the application program. The image IMG to be displayed on the display unit 2B of the device under test 2 is transformed by the processing unit 2C using the calibration transformation matrix CTM read from the calibration data memory 2A to provide the corrected image IMG′ output by the display unit 2B to the user of the device under test 2. The image IMG to be displayed on the display unit 2B can form part of a video image sequence comprising a plurality of images or image frames. FIG. 4 shows a flowchart for illustrating the calibration as performed by the calibration setup as shown in FIG. 3 after having calculated the calibration transformation matrix CTM in steps S1, S2, S3, the device under test 2 is calibrated with said calibration transformation matrix CTM in step S4 to increase the image quality of images displayed to the user.

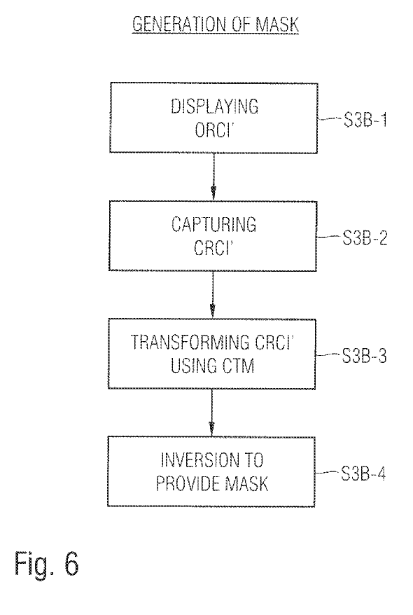

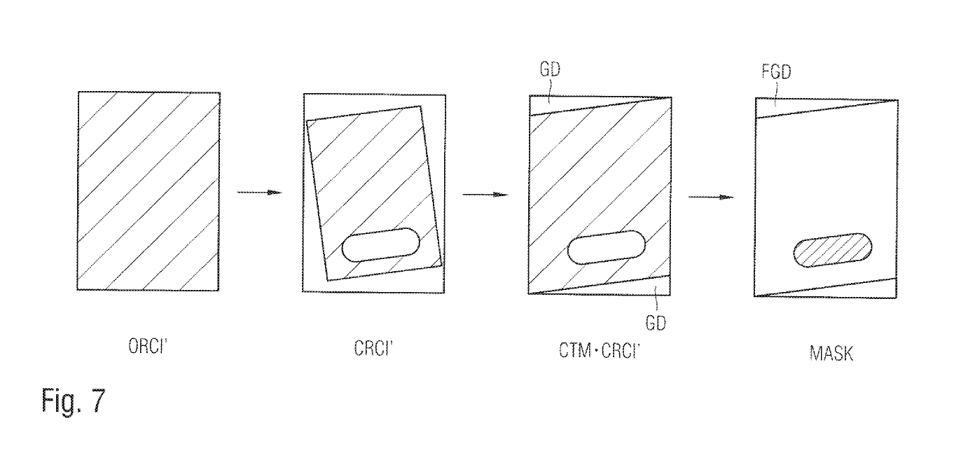

In a possible embodiment of the device under test 2, the calibration transformation matrix CTM is optimized after having being stored in the calibration memory 2A of the device under test 2. This is illustrated in the flowchart shown in FIG. 5. After having calculated the calibration transformation matrix CTM in steps S1, S2 and S3A, the calculated calibration transformation matrix CTM is further modified in step S3B before being written back into the calibration memory 2A of the device under test 2 in step S4. For modification of the calibration transformation matrix CTM a mask is generated as illustrated in the flowchart of FIG. 6. For generation of the mask a further reference calibration image oRCI′ is displayed. The second reference calibration image oRCI′ can be formed in a preferred embodiment by a uniform color calibration image, for example by the uniform color calibration image oRCI′ as illustrated in FIG. 7. This uniform color reference calibration image oRCI′ is displayed and captured to get a captured uniform color calibration image cRCI′ as also shown in FIG. 7. The captured uniform color calibration image cRCI′ comprises superimpositions generated by the application program run on the device under test 2. As shown in FIG. 6 for generating the mask, the original uniform color calibration image oRCI displayed in step S3B-1 is captured in step S3B-2. In a further substep, the captured uniform color reference calibration image cRCI′ is then transformed in step S3B-3 using the calibration transformation matrix CTM calculated in step S3A as shown in FIG. 5.

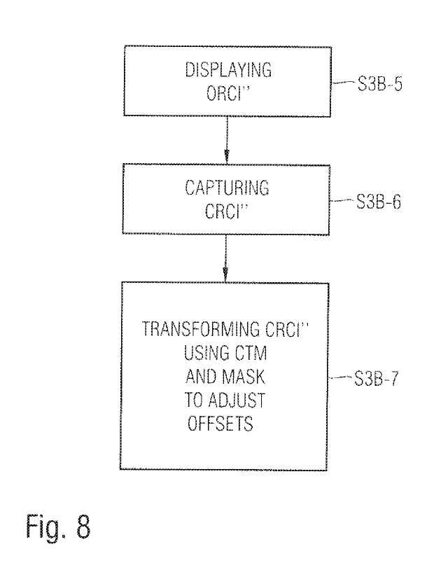

In a possible implementation, the captured uniform color reference calibration image cRCI′ is transformed by multiplying the two-dimensional calculated calibration transformation matrix CTM with the captured uniform color reference calibration image cRCI′ as illustrated also in FIG. 7. The transformed captured uniform color calibration image oRCI′ is then inverted to generate an image mask in step S3B-4 as also illustrated in FIG. 7. As can be seen from FIG. 3 and FIG. 7, the transformed image IMG′ as well as the generated mask image MASK still comprise some misalignments or unwanted geometric distortions GD. To reduce these geometric distortions GD the originally calculated calibration transformation matrix CTM is optimized to provide an even higher visual quality. For this purpose, a test pattern forming a further reference calibration image oRCI″ is displayed and captured to generate a captured test pattern cRCI″ which is then transformed using the generated image mask MASK provided by the routine shown in FIG. 6 wherein the calculated calibration transformation matrix CTM is iteratively modified for geometric fine adjustment and color correction until an error between the captured and transformed test pattern and the original test pattern is minimized. This is also illustrated in the flowchart shown in FIG. 8.

As can be seen in FIG. 8, in a first substep S3B-5 following substep S3B-4 of FIG. 6, a test pattern forming a third reference calibration image oRCI″ is captured in step S3B-6 to provide a captured reference calibration image oRCI″ which is transformed in step S3B-7 using the generated image mask MASK and the calibration transformation matrix CTM wherein the calibration transformation matrix CTM is iteratively modified for geometric fine adjustment and color correction until an error between the captured and transformed test pattern is minimized. Finally, the test pattern oRCI″ is used for fine adjustment and color correction. The test pattern comprises in a possible embodiment multiple patterns. These multiple patterns can comprise patterns of different colors or grid patterns of different granularity. The test pattern oRCI″ can be a complex test pattern with a wide range of colors and/or geometric structures. While applying the calculated calibration transformation matrix CTM and using the generated mask MASK for masking superimpositions generated by the application program an image is generated that is relatively close to the applied test pattern forming the reference calibration image. In step S3B-7, the original calibration transformation matrix CTM can be systematically modified. For example, each coordinate of the image can be slightly moved or shifted and a PSNR per pixel comparison with the reference calibration image can be performed to check whether this improves the image quality or not.

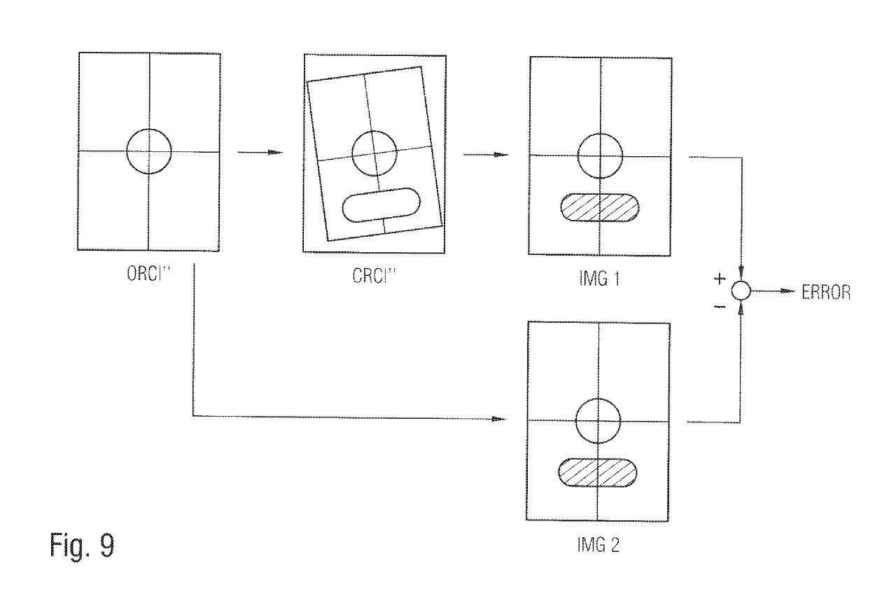

This is illustrated in the schematic diagrams of FIG. 9. As can be seen in FIG. 9, the complex test pattern oRCI″ is displayed in step S3B-5 and captured in step S3B-6 to provide the captured test pattern cRCI″ as illustrated in FIG. 9. This captured test pattern oRCI″ is then transformed using the image mask generated in the routine shown in FIG. 6 and using the calculated calibration transformation matrix CTM to calculate a first image IMG1 as shown in FIG. 9.

In a possible implementation, the first image IMG1 is calculated as follows:

IMG₁−cRCI″*CTM*OFFSET*COLOROFFSET−MASK*OFFSET (1)

Further, a second image IMG2 is calculated as follows:

IMG₂=oRCI″−MASK*OFFSET (2)

In a further substep, an error between the first image IMG1 and the second image IMG2 is calculated:

ERROR=IMG1−IMG2 (3)

The offset value OFFSET and the color offset value COLOROFFSET are then iteratively adjusted until the calculated error ERROR becomes minimal. This provides a geometric fine adjustment and color correction of the original calibration transformation matrix CTM. In a possible implementation, a systematic modification of the calibration transformation matrix CTM is done by iterative adjustment of the offset value and color offset value to minimize the error. This can be achieved by performing a PSNR per pixel comparison with the reference calibration image, or alternatively simulated annealing can be performed or a genetic algorithm can be applied. Finally, the geometric offset OFFSET and/or the color offset COLOROFFSET is iteratively adjusted until the calculated error becomes minimal. The modified calibration transformation matrix CTM can then be stored by the calibration apparatus 1 in the calibration memory 2A of the device under test 2. By application of the optimized calibration transformation matrix. CTM stored in the calibration memory 2A of the device under test 2 the video or image quality is significantly improved. In particular, geometric distortion GD is removed. Further, unwanted artifacts are avoided. Further coloration is prohibited which may be caused by an automatic brightness adjustment or technical limitations of the display unit or camera of the device under test 2. With the calibration method according to the present invention, the image quality is improved by removing distortions comprising rotations or recoloring or reflections. After calibration of the device under test 2, the display unit of the device under test 2 provides images of high visual quality. The displayed corrected images comprise almost no geometric distortions and unwanted obstructions on the planar display unit are removed. In a possible embodiment, the display unit of the device under test 2 is a touchscreen. In a still further possible embodiment, the display unit can also be a beamer projecting an image to a wall.

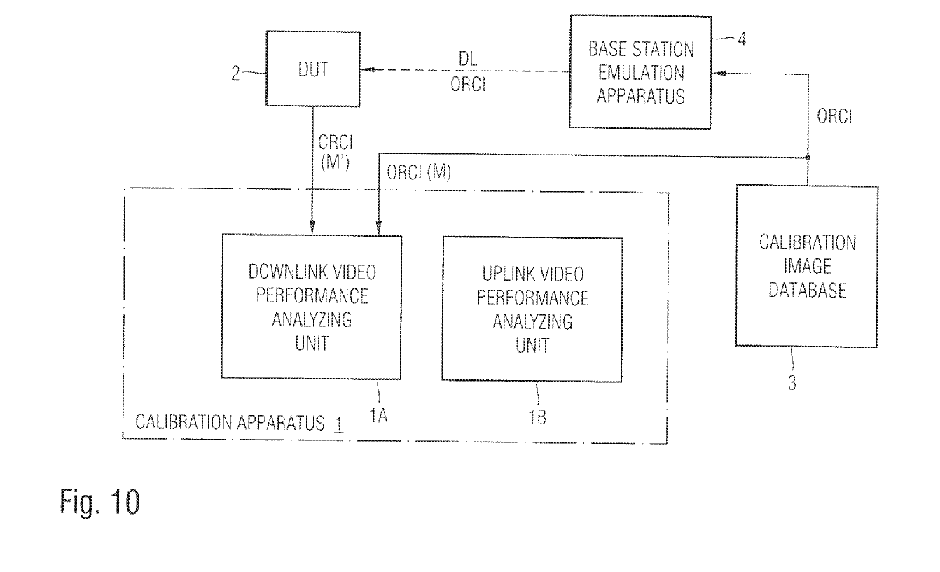

FIG. 10 shows a block diagram for illustrating a possible further embodiment of a calibration apparatus 1 according to a further aspect of the present invention. In the illustrated embodiment, the calibration apparatus 1 comprises a downlink video performance analyzing unit 1A and an uplink video performance analyzing unit 1B. The downlink video performance analyzing unit 1A is adapted to analyze a downlink video performance of a device under test 2 such as a smartphone. The uplink video performance analyzing unit 1B is adapted to analyze an uplink video performance of the device under test 2. The downlink video performance analyzing unit 1A and/or the uplink video performance analyzing unit 1B comprise a processing unit adapted to calculate a calibration transformation matrix CTM for the respective device under test 2 on the basis of markers M of a reference calibration image oRCI and Markers M′ of a captured reference calibration image cRCI. For example, an original reference calibration image oRCI and a captured calibration image cRCI are illustrated in FIGS. 2A, 2E. In a possible embodiment, the processing unit of the calibration apparatus 1 can perform a program for executing program instructions to perform a method for calibration as illustrated in context with FIG. 1.

FIG. 10 illustrates the operation of the downlink video performance analyzing unit 1A of the calibration apparatus 1. The downlink video performance analyzing unit 1A of the calibration apparatus 1 is adapted to receive a captured reference calibration image cRCI containing the markers from the device under test 2. The reference calibration image can be captured by an image capture component, in particular a software capture component of the device under test 2 and supplied to the downlink video performance analyzing unit 1A via a data interface or a databus. For instance, the captured image reference calibration CRCI can be supplied by an image capture software component of the device under test 2 via an USB bus to an input of the downlink video performance analyzing unit 1A. The downlink video performance analyzing unit 1A receives an original reference calibration image oRCI from a calibration image database 3 as shown in FIG. 10. In a possible embodiment, the original reference calibration image oRCI is also supplied to a base station emulation apparatus 4, for instance an LTE eNodeB emulator. The base station emulation apparatus 4 is configured to transmit the original referenced calibration image oRCI via a wireless downlink connection to a receiver device under test 2 being displayed on a display unit of the device under test 2. The software image capturing component of the device under test 2 can capture the displayed reference calibration image CRCI and then supply it to the downlink video performance analyzing unit 1A as illustrated schematically in FIG. 10. The reference calibration image oRCI can form part of a sequence of reference calibration images. The downlink video performance analyzing unit 1A analyzes a downlink video performance of the device under test 2. This can be performed to increase the video quality of a video sequence displayed on a display unit of the device under test 2 in response to a sequence of images or video received by a receiver of the device under test 2 via a wireless link base station of a telecommunication system. As illustrated in FIG. 10, the downlink video performance analyzing unit 1A can comprise a processing unit which calculates a downlink calibration transformation matrix CTM_{DL}, that can be stored in a calibration memory of the device under test 2. The stored downlink calibration transformation matrix CTM_{DL} can be used during operation of the calibrated device under test 2 receiving images via a wireless downlink DL to be displayed on the display unit of the device under test 2. In a possible embodiment, the downlink video performance analyzing unit 1A performs a geometric fine adjustment and color correction of the downlink calibration transformation matrix CTM.

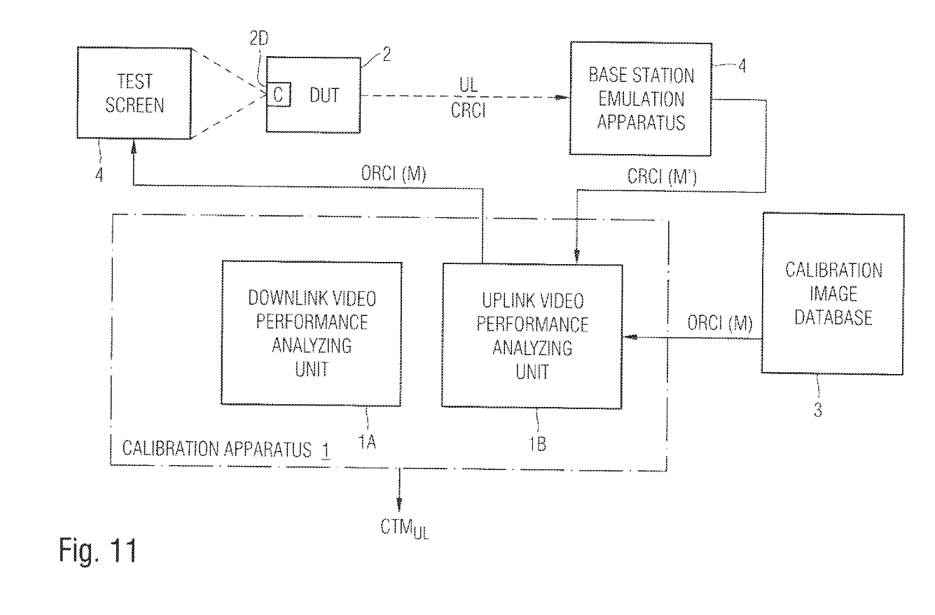

FIG. 11 shows a block diagram for illustrating the operation of the uplink video performance analyzing unit 1B of the calibration apparatus 1 in a calibration setup. As can be seen in FIG. 11, the uplink video performance analyzing unit 1B of the calibration apparatus 1 can be connected to a test screen 4. The test screen 4 is adapted to display a reference calibration image oRCI supplied by the uplink video performance analyzing unit 1B via a data interface or a databus to the test screen 4. The uplink video performance analyzing unit 1B receives the original reference calibration image oRCI from a calibration image database 3 and supplies the reference calibration image oRCI having markers M to the test screen 4. The reference calibration image oRCI can form part of a sequence of reference calibration images, a reference calibration image video sequence. The original reference calibration image or reference calibration images oRCI having the markers M are displayed on the test screen 4 and the displayed reference calibration image is captured by a camera 2D integrated in the device under test 2 as shown in FIG. 11. In an alternative embodiment, the camera 2D is not integrated in the device under test 2 but connected to the device under test 2 via an interface. The reference calibration image displayed on the test screen 4 is captured by the camera 2D to generate the captured reference calibration image cRCI supplied to the uplink video performance analyzing unit 1B of the calibration apparatus 1. This can be performed in a possible embodiment via a wireless uplink connection as shown in FIG. 11. In this embodiment, the displayed reference calibration image captured by the camera 2D is transmitted by a transmitter of the device under test 2 via a wireless uplink UL to a base station emulation apparatus 4 connected to the uplink video performance analyzing unit 1B of the calibration apparatus 1. The emulation apparatus 4 can be for instance an LTE eNodeB emulation apparatus emulating an eNodeB of an LTE communication system. Accordingly, the uplink video performance analyzing unit 1B receives the captured reference calibration image cRCI containing the markers M′ from the base station emulation apparatus 4 for further processing. The uplink video performance analyzing unit 1B comprises in a preferred embodiment a processing unit adapted to calculate a calibration transformation matrix CTM of the device under test 2 on the basis of the markers M within the reference calibration image oRCI forwarded by the calibration image database 3 and on the basis of the markers M′ of the received captured reference calibration image cRCI read from the base station emulation apparatus 4. The uplink video performance analyzing unit 1B is adapted to calculate an uplink calibration transformation matrix CTM_{UL} on the basis of the markers M and the markers M′. The calculated matrix CTM_{UL} is then stored in a calibration memory of the device under test 2 for calibrating the device under test 2. Accordingly, in a possible embodiment, the calibration memory 2A of the device under test 2 stores two different calibration transformation matrices CTM_{DL}, CTM_{UL} used for a downlink connection and an uplink connection.

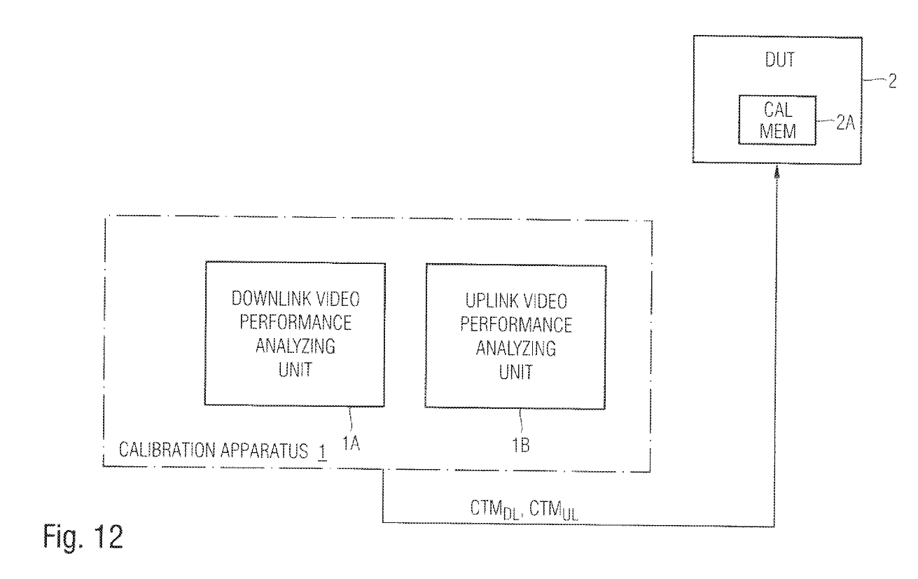

This is illustrated in the schematic diagram of FIG. 12. The calibration method and calibration apparatus according to the present invention can be used for removing different kinds of distortions at the same. Distortions can comprise stretching where an image width is reduced by a factor, a translation or shift where the image is not centered on the display unit, a cutoff where the image has missing parts at the left or right side of the display or obstructions of a graphical user interface GUI such as buttons or other artifacts, for instance compression artifacts. The fine tuning of the calibration transformation matrix CTM can be performed by using a mask, in particular a binary mask generated from a reference calibration image. The reference calibration image for generating the mask is in a preferred embodiment a uniform color reference calibration image and can be for instance generated by blue chroma keying. In a possible implementation, by using the coordinates detected in QR codes in the reference calibration image RCI the reference calibration image can be translated to the same position as the original source reference calibration image. In a preferred embodiment, multiple smaller QR codes spaced apart and located in the periphery of the reference calibration image are used.

According to a further aspect, of the present invention, a base station emulation apparatus 4 is provided in the calibration setup illustrated in FIGS. 10, 11. The base station emulation apparatus 4 can comprise an LTE eNodeB emulation apparatus. The base station emulation apparatus 4 is adapted to transmit a reference calibration image via a wireless downlink DL to a receiver of a device under test 2 such as a smartphone. The original reference calibration image oRCI is displayed by a display unit 2B of the device under test 2 and captured to generate a captured reference calibration image cRCI supplied to a downlink video performance analyzing unit 1A of a calibration apparatus 1. The base station emulation apparatus 4 is further adapted to receive a captured reference calibration image cRCI via a wireless uplink UL from a transmitter of the device under test 2 and supplies the captured reference calibration image cRCI to an uplink video performance analyzing unit 1B of an calibration apparatus 1. The reference calibration image RCI provided by the uplink video performance analyzing unit 1B of the calibration apparatus 1 can be displayed on a test screen and then captured by a camera of the device under test 2 as illustrated in FIG. 11. In a further possible embodiment, the calibration apparatus 1 can be integrated in the base station emulation apparatus 4. The base station emulation apparatus 4 can have access to a calibration image database 3 via a data network.

1. A method for calibrating a device under test, DUT, comprising the steps of:
(a) displaying an original reference calibration image, oRCI, having at least one marker, M;
(b) capturing the displayed original reference calibration image, oRCI, to generate a captured reference calibration image, cRCI; and
(c) calculating a calibration transformation matrix, CTM, for said device under test, DUT, on the basis of the at least one marker, M, of the original reference calibration image, oRCI, and on the basis of the at least one marker, of the captured reference calibration image, cRCI.

2. The method according to claim 1 wherein the reference calibration image, oRCI, is read from a calibration image database.

3. The method according to claim 1 wherein the calibration transformation matrix, CTM, is calculated by a processing unit of a calibration apparatus depending on markers, M, contained in the original reference calibration image, oRCI, read from calibration image database and depending on markers, M′, contained in the captured reference calibration image, cRCI.

4. The method according to claim 1 wherein the reference calibration image, oRCI, is displayed a display unit of the device under test, DUT.

5. The method according to claim 4 wherein the reference calibration image, oRCI, displayed on the display unit of the device under test, DUT, is captured by an image capture component of said device under test, DUT, or by a camera to generate the captured reference calibration image, cRCI, which is supplied to a calibration apparatus connected to the device under test, DUT.

6. The method according to claim 1 wherein the original reference calibration image, oRCI, read from a calibration image database is transmitted by a base station or by a base station emulation device via a wired or wireless downlink, DL, to a receiver of the device under test, DUT, and displayed on a display unit of the device under test, DUT.

7. The method according to claim 1 wherein the original reference calibration image, oRCI, read from a calibration image database is displayed on a test screen.

8. The method according to claim 7 wherein the reference calibration image, oRCI, displayed on said test screen is captured by a camera connected to said device under test, DUT, or by a camera integrated in said device under test, DUT, to generate the captured reference calibration image, cRCI, which is supplied to calibration apparatus.

9. The method according to claim 8 wherein the displayed reference calibration image, oRCI, captured by said camera is transmitted by a transmitter of said device under test, DUT, via a wired or wireless uplink, UL, to a base station or to a base station emulation device connected to said calibration apparatus.

10. The method according to claim 1 wherein the markers, M, of the reference calibration image, oRCI, are positioned at a periphery of the reference calibration image, RCI.

11. The method according to claim 1 wherein the markers, M, of the reference calibration image, oRCI, comprise unique markers each having a unique form and/or having a unique code pattern.

12. The method according to claim 1 wherein the calculated calibration transformation matrix, CTM, is written in a calibration data memory of the device under test, DUT.

13. The method according to claim 12 wherein an image to be displayed by a display unit of said device under test, DUT, is transformed during operation of said device under test, DUT, using the calibration transformation matrix, CTM, read from the calibration data memory of said device under test, DUT, to provide a corrected image output by the display unit of said device under test, DUT.

14. The method according to claim 13 wherein the image to be displayed on the display unit of the device under test, DUT, forms part of a video image sequence.

15. The method according to claim 1 wherein a uniform color calibration image, oRCI, is displayed and captured to generate a captured uniform color calibration image, comprising superimpositions generated by an application program run on said device under test, DUT.

16. The method according to claim 15 wherein the captured uniform color calibration image, cRCI′, is transformed using the calculated calibration transformation matrix, CTM, to calculate a transformed captured uniform color calibration image which is inverted to generate an image mask (MASK).

17. The method according to claim 16 wherein a test pattern, oRCI″, is displayed and captured to generate a captured test pattern, cRCI″, which is transformed using the image mask, MASK, and the calculated calibration transformation matrix, CTM, which is iteratively modified for geometric fine adjustment and color correction until an error between the captured and transformed test pattern, cRCI″, and the original test pattern, oRCI″, is minimized.

18. The method according to claim 17 wherein the fine adjusted modified calibration transformation matrix, CTM, is written into a calibration data memory of the device under test, DUT.

19. A calibration system for calibrating a device under test, DUT, said calibration system comprising:
(a) means for displaying an original reference calibration image, oRCI, having at least one marker, M;
(b) means for capturing the displayed reference calibration image, oRCI, to generate a captured reference calibration image, cRCI; and
(c) means for calculating a calibration transformation matrix, CTM, for said device under test, DUT, on the basis of the at least one marker, M, of the original reference calibration image, oRCI, and on the basis of the at least one marker, M′, of the captured reference calibration image, cRCI.

20. A calibration apparatus for calibration of a device under test, DOT, said calibration apparatus comprising:
a downlink video performance analyzing unit adapted to analyze a downlink video performance of said device under test, DUT, and/or
an uplink video performance analyzing unit adapted to analyze an uplink video performance of said device under test, DOT,
wherein the downlink video performance analyzing unit and/or the uplink video performance analyzing unit comprises a processing unit adapted to calculate a calibration transformation matrix, CTM, of said device under test, DOT, on the basis of markers, M, of a reference calibration image, oRCI, and markers, M′, of a captured reference calibration image, cRCI.

21. The calibration apparatus according to claim 20 wherein the downlink video performance analyzing unit of said calibration apparatus is adapted to receive a captured reference calibration image, cRCI, on said device under test, DUT, wherein the reference calibration image, oRCI, is captured by an image capture component of said device under test, DOT, and supplied to said downlink video performance analyzing unit via a data interface or the reference calibration image, oRCI, is captured by a camera connected to the downlink video performance analyzing unit of said calibration apparatus.

22. The calibration apparatus according to claim 20 wherein the uplink video performance analyzing unit of said calibration apparatus is connected to a test screen adapted to display a reference calibration image, oRCI, wherein the reference calibration image, oRCI, displayed on said test screen is captured by a camera connected to said device under test, DUT, or by a camera integrated in said device under test, DUT, to generate the captured reference calibration image, cRCI, which is supplied to the uplink video performance analyzing unit of said calibration apparatus.

23. The calibration apparatus according to claim 22 wherein the displayed reference calibration image, oRCI, captured by said camera is transmitted by a transmitter of said device under test, DUT, via a wireless uplink, UL, to a base station or to a base station emulation apparatus connected to the uplink video performance analyzing unit of said calibration apparatus.

24. A base station emulation apparatus adapted to transmit a reference calibration image, RCI, via a downlink, DL, to a receiver of a device under test, DUT, said reference calibration image, RCI, being displayed by a display unit of said device under test, DUT, and captured to generate a captured reference calibration image, cRCI, applied to a downlink video performance analyzing unit of a calibration apparatus and adapted to receive a captured reference calibration image, cRCI, via a uplink, UL, from a transmitter of the device under test, DUT, and to supply the captured reference calibration image, cRCI, to an uplink video performance analyzing unit of the calibration apparatus, wherein the reference calibration image, RCI, provided by said uplink video performance analyzing unit of said calibration apparatus is displayed on a test screen and captured by a camera of said device under test, DUT.
